(19) United States
(12) Patent Application Publication
(10) Pub. No.: US 2009/0208672 A1
(43) Pub. Date: Aug. 20, 2009

(54) Method of linear patterning at surfaces

(76) Inventors: John C. Polanyi, Toronto (CA); Krishnan R. Harikumar, Toronto (CA); Iain Ross McNab, Toronto (CA); Werner A. Hofer, Liverpool (GB)

Correspondence Address: Ralph A. Dowell of DOWELL & DOWELL P.C., 2111 Eisenhower Ave, Suite 406, Alexandria, VA, 22314, US

(21) Appl. No.: 12/320,628

(22) Filed: Jan. 30, 2009

Related U.S. Application Data
(60) Provisional application No. 61/006,772, filed on Jan. 30, 2008.

(51) Int. Cl. C23C 14/28; B05D 5/12

(52) U.S. Cl. 427/596; 427/58; 427/595

(57) ABSTRACT

The present invention provides a process for partially covering solid crystalline surfaces with lines of selected atoms or molecules, a procedure known as the atomic or molecular ‘patterning’ of such surfaces. The method utilizes a mechanism of Dipole-Induced Assembly (DIA) for the growth of lines of physisorbed dipolar molecules on crystalline surfaces is disclosed. In an exemplary embodiment, physisorbed 1,5 dichloropentane (DCP) on Si(100)−2×1 at room temperature is shown by scanning tunneling microscopy (STM) to self-assemble into molecular lines that grow predominantly perpendicular to the Si-dimer rows. Extensive simulations indicate that the trigger for formation of these lines is the displacement of surface charge by the dipolar adsorbate, giving rise to an induced uni-directional surface-field and hence surface buckling.

### CROSS REFERENCE TO RELATED U.S. APPLICATION

This patent application relates to, and claims the priority benefit from, U.S. Provisional Patent Application Ser. No. 61/006,772 filed on Jan. 30, 2008, in English, entitled METHOD OF LINEAR PATTERNING AT SURFACES, and which is incorporated herein by reference in its entirety.

### FIELD OF THE INVENTION

The present invention relates to a method for pattern imprinting of lines, on an atomic or molecular-scale, on the surface of a solid by inducing localized chemical reaction between adsorbate molecules and the surface of the solid.

### BACKGROUND OF THE INVENTION

One-dimensional nanostructures at silicon surfaces have potential applications in nano-scale devices, particularly in nanoelectronics, which necessitates non-lithographic ways of creating interconnects at the nanometer scale. Over the last decade systems have been sought that yield self-assembled atomic or molecular lines on semiconductors. Progress in the hundred billion dollar semi-conductor industry depends, in part, on the ability to mark (i.e. write, dope or etch) a surface with small features at controlled separations. The current limit is the making of marks separated by a few tenths of a nanometer (commonly 0.3 microns, i.e. 3,000A, which is roughly one thousand atoms separation). Patterns of these dimensions constitute the lower limit of what can be achieved by the conventional method of marking, which involves the use of a patterned mask to shield portions of the surface from the agent (electrons, light or chemicals) used in order to mark the surface. It has not proved possible to make patterned masks having features smaller than tenths of a micron. Moreover, masks with such small features already suffer from irreproducibility.

U.S. Pat. No. 5,645,897 issued to Andra discloses a method for surface modification by ion bombardment of the surface or the region in front of the surface portion being etched or coated. The ion source is chosen to produce ions which are highly charged and possessing kinetic energies sufficiently high to permit the ions to approach the surface but low enough to prevent penetration of the surface. A stated advantage of the process of this patent is that the highly charged state of the ions and their low kinetic energies results in very localized energy deposition thereby giving rise to improved spatial resolution in the imprinting of patterned masks for etching or coating the surface. This patent also discloses combining the feature of localized energy deposition using the ion beams with conventional lithographic masking techniques for producing precise etching patterns.

U.S. Pat. No. 5,405,481 issued to Licoppe et al. is directed to a gas photo-nanograph device for production of nanometer scale surface patterns. The device includes a head comprising a fiber optic cable terminating in a tip and microcapillary channels also terminating at the tip that feed reactive gas from a gas reservoir. The tip is spaced from the area of the substrate surface being light activated. Nanopatterns can be produced by scanning this device, as one might write with a pen, the tip of the pen here being a focused light source.

U.S. Pat. No. 4,701,347 issued to Higashi specifically mentions the photolysis of molecules adsorbed on a surface as a method for growing patterned metal layers on semiconductor. However, in common with earlier patents cited therein, going back to U.S. Pat. No. 3,271,180 issued on Sep. 6, 1966, the pattern of photolytic and thermal reaction induced by illumination of the adsorbate derives from the presence of a mask between the light source and the adsorbed layer.

U.S. Pat. No. 5,322,988, in common with U.S. Pat. No. 4,701,347 referred to above, uses laser irradiation to induce photochemical and thermal reaction between an adsorbate layer and the underlying substrate, but the reaction etches rather than writes (the etching is termed “texturing”). Reaction, it is stated, only occurs where the laser is impinging with sufficient fluence, i.e. patterned illumination (as beneath a “mask”) is the source of patterned etching.

D. J. Ehrlich et al. in Appl. Phys. Lett. 36, 698 (1980) describe a method of mask-free etching of semiconductors based on the ultraviolet photolysis of gaseous methyl halides. The place of the patterned mask is taken by an interference pattern, i.e. it derives, once more, from patterned irradiation of the surface ather than, as here, from a pattern of adsorbate molecules.

U.S. Pat. Nos. 4,608,117 and 4,615,904 issued to Ehrlich et al., disclose maskless growth of patterned films. This method describes a two-step process. In step one a pattern is written on the surface using a focused light-beam or electron-beam as a pen, and photodissociation as the agent for writing. Once a 1-2 monolayer pattern of metal or semiconductor has been written in this fashion, step two involves uniform irradiation of the gaseous reagent and the surface which results in the accumulation of material on the “prenucleated sites”, i.e. in the close vicinity of the pattern of deposition formed in step one. Consequently this second growth-phase is mask-free. In the mask-free film-growth phase “atoms are provided dominantly by direct photodissociation of the gas-phase organometallic molecules . . . ” (U.S. Pat. No. 4,608,117, column 2, lines 12 and 13). Film growth, it is stated, occurs selectively in the prenucleated regions where impinging atoms originating in the gas phase have a higher sticking coefficient at the surface.

M. Balooch and W. J. Siekhaus, Nanotechnology, Z, (1996) 365-359, report on the adsorption of XeF₂ on a Si surface. They teach how to produce a silicon vacancy by bringing the tip of the STM down to the surface and then applying a voltage pulse between the STM tip and the surface. An etching reaction occurs at the point where the STM tip produces a highly localized and strong electric field. Balooch teaches producing an individual mark comprising ejection of a silicon atom. Such a method of marking a surface, by ‘writing’ on it, an atom at a time, is not amenable to producing large scale patterns across the surface as required in many applications, due to the length of time needed to re-position the STM each time to produce an atomic scale mark and the ˜10¹⁰ or more atoms in a macroscopic device.

U.S. Pat. No. 5,129,991 issued to Gilton describes an alternative scheme for mask-free etching. An adsorbed etch-gas (a chloride or fluoride) is present on a substrate which has macroscopic regions fabricated from different materials having different photoemission threshold-values for the release of electrons. This substrate is illuminated with a wavelength of light selected to give electron emission from some regions but not from others. The emitted electrons cause etching to occur only on those regions of the substrate which are composed of materials with a low enough photoemission threshold to emit electrons; i.e., reaction is localised, but localised to macroscopic areas.

C. Yan et al., J. Phys. Chem., 99 6084 (1995), have reported that molecular chlorine impinging as an energetic (0.11 eV) beam of molecules on a Si(111)7×7 substrate reacts directly from the gas to halogenate the substrate preferentially at surface silicon-atom sites which are adjacent to one another (70% adjacent, 30% non-adjacent). Though these chlorinated pairs of sites recur randomly across the surface, they constitute short-range order, i.e., a simple form of molecular-scale patterning.

One of the inventors on the present application (John Polanyi) has described and patented a ‘Method of molecular-scale pattern imprinting at surfaces’ (Polanyi et al., U.S. Pat. Nos. 6,156,393, of Dec. 5, 2000; 6,319,566 of Nov. 20, 2001; and 6,878,417 of Apr. 12, 2005), all of which are incorporated herein by reference in their entirety. The method of these prior patents involved patterned self-assembly of physisorbed molecules at a surface, followed by imprinting of the nano-scale pattern at the underlying surface through localized reaction induced by irradiation using light, electrons or ions. (Such a device is effectively a molecular-scale printing press, in which the self-assembled adsorbate constitutes the ‘ink’, the pattern of adsorbate the ‘type’, and the irradiation the ‘press’). These patents, while showing that self-assembled adsorbate patterns could be permanently imprinted, do not teach how to for example produce patterned lines and the like, which would be very useful in preparing for example nanocircuits.

Thus it would be important to provide a method of imprinting of lines, on an atomic or molecular-scale, on the surface of solids by inducing localized chemical reaction between lines of adsorbate molecules and the surface of the solid.

### SUMMARY OF THE INVENTION

The present invention discloses a method for the self-assembly of molecular ‘inks’ as lines on surfaces, providing a new category of ‘inks’ and thus new ‘type’ for the earlier ‘Method of molecular-scale pattern imprinting at surfaces”.

It is an object of the invention to provide a process for partially covering solid crystalline surfaces with lines of selected atoms or molecules (the ‘ink’), a procedure known as the atomic or molecular ‘patterning’ of such surfaces. The process by which this ink self-assembles into lines, is disclosed herein for the first time.

Thus in an embodiment the present invention provides a method of mask-free linear atomic- or molecular-patterning of crystalline surfaces by physisorptive or chemical self-assembly, comprising the steps of:

a) an initiation step including exposing a surface of an electrically polarizable crystalline solid with a gas of initiator atoms or molecules selected to attach to said surface at an initiator site and having a property of inducing a charge-displacement, hence a dipole moment, at a point of attachment at the initiator site with resultant local displacement of a surface atom or atoms at that site, giving rise to surface-strain and hence surface ‘buckling’ at that initiator site, which buckling propagates along a crystal axis causing buckling at least one adjacent site along that axis, and

b) following the initiation step, exposing the surface to a dosing gas containing atoms or molecules that bathe the surface, which dosing gas may have the same chemical composition or different chemical composition from the initiator gas, but which atoms or molecules of the dosing gas are sufficiently mobile to self-assemble and which are attracted to the aforementioned buckled site or sites adjacent to the initiator site so that a line originating from the initiator site “propagates’, sequentially, an atom or a molecule at a time, each atom or molecule once more causing charge-displacement and adjacent buckling so that a line grows away from the initiator site by accretion of physisorbed or chemisorbed atoms or molecules from the gas.

A ‘line’ in this usage includes a sequence of ‘ink’ molecules adjacent to one another. It may or may not be a straight line, though in many preferred applications and in the examples cited it will be a straight line.

Without being bound by any theory, in the method of the present invention, the lines are initiated by exposing the clean surface to a gas of atoms or molecules (the ‘initiators’) capable of displacing charge at or near the point of attachment, giving rise to a local surface-dipole or ‘charge perturbation’. Such charge displacement is common in both physisorption and chemisorption, being due to the different affinity of adsorbate and substrate for electrons, and being related to the attraction that binds the adsorbate to the substrate. The charge-perturbation at the site of adsorption has a direction; i.e. it is a ‘vector’ quantity.

Attachment of the above initiator atoms or molecules responsible for starting a line can be either by weak physical forces (i.e. ‘physisorption’) or stronger chemical forces (‘chemisorption’), it being only necessary that charge-displacement occurs at the site of attachment. Charge-displacement is common since the act of physisorption or chemisorption is charge-perturbative. The charge-displacement can itself induce the component molecules of the line to react chemically with the surface. Alternatively chemical reaction can be induced by heat, light or electrons subsequent to line-formation.

Following initiation the line ‘propagates’, sequentially, an atom or a molecule or combinations of molecules such as dimers, trimers, etc. at a time, away from the initiator site by accretion of physisorbed or chemisorbed atoms or molecules from a gas that bathes the surface, which gas may have the same chemical composition or different chemical composition from the initiator gas, but which gas also has the property of inducing a charge-perturbation at the point of attachment.

The cause of the preferred linear attachment of the propagator atoms or molecules (the ‘ink’) is the initial localised charge-perturbation that alters the interatomic forces in the surface, introducing a localized and directed vectorial strain (‘induced strain’) with resultant displacement of at least one adjacent surface site along a preferred direction, which site-displacement we term ‘buckling’. This method of line-growth is applicable to crystalline surfaces that transmits strain linearly, such surfaces being characterized by linear cleavage planes.

Buckled surface sites differ from unbuckled in the atomic environment of the buckled surface atom or group, and therefore in their electronic charge-cloud. As a consequence they have a different physical or chemical affinity for (randomly) impinging gaseous atoms or molecules, as well as for atoms or molecules diffusing across the surface. In the case that the affinity is increased, the effect of further dosing with gas is to grow a line, sequentially atom by atom or molecule by molecule, along a direction related to the direction of the adjacent charge-transfer vector, as demonstrated in the examples cited. Additionally, line-growth occurs preferentially along symmetry axis' of the underlying crystalline surface, the precise outcome being a net consequence of both influences.

As many ‘ink’ lines can be grown concurrently as initiators are dosed on the surface in the first step. These lines, if initiated by a single chemical species attached to the surface, with, therefore, a single alignment of the induced strain relative to the surface crystalline axis', will give rise to parallel lines. Parallel non-intersecting lines will have applications, for example, for high-current nanocircuitry, since they constitute electric-cabling at the nanoscale.

The chemical nature of the atoms or molecules comprising the line or lines can be changed by changing the dosing gas. This can be done at any time during line-growth, resulting in multi-component lines. (Such lines, since they can form electrically-conducting wires with multiple chemical junctions, could be suited, for example, to photovoltaic applications).

By a suitable change in dosing gas one can, therefore, change the direction of line-growth. This is useful in drawing desired variable molecular-scale patterns. This step of changing the dosing gas causes, due to a change in the dipolar axis of the adsorbate molecule relative to the surface symmetry axis', a change in the induced strain at the surface alters the direction of line-growth for preparing variable molecular-scale patterns.

The direction of line-growth is governed by the charge-perturbation vector at the surface (and hence the direction of the induced strain) due to the prior surface-attached atom or molecule of the line. This, in turn, depends on the chemical nature of the material dosed and thereby attached to the surface.

### BRIEF DESCRIPTION OF THE DRAWINGS

The patent or application file contains at least one drawing executed in color. Copies of this patent or patent application publication with color drawing(s) will be provided by the Office upon request and payment of the necessary fee. The method of marking or patterning a surface with lines on a molecular scale forming the subject of this invention will now be described, reference being made to the accompanying Figures.

FIG. 1 shows self-assembled molecular nanolines at room temperature. a A room temperature STM image (270 Å×270 Å) of a Si (100)−2×1 surface exposed to 1 L nominally (an uncorrected pressure of 5×10⁻⁹ Torr, 200s) of DCP. Lines of DCP are imaged as bright features mostly perpendicular to the Si dimer rows with some 5% at 23° to the dimer rows (example circled). The direction of line growth is known, and is shown for some cases by white arrows. Individual DCP features (bright protrusions) lie to one side of the dimer rows. b perspective and top-view (inset); black dashed lines denote the center of the Si-dimer rows throughout, blue spheres denote Cl-atoms and blue dotted lines the physisorption interaction; the black arrows indicate the adsorbate dipoles and the long red arrow points to the direction of line growth. The model of 1,5 DCP is shown in the inset. c Close up (60 Å×40 Å) of the nanoline taken from the highlighted white frame in a. d As in c: red and black ellipses denote dimers and defects respectively, black-dashed and gray lines indicate the centre of the ridges (center) and the valleys of the dimer rows. From this picture it is evident that the molecular features (bright protrusions) lie to one side of the dimer rows (to the right as we have oriented a-e). A height profile taken along the blue line in the STM image e is shown in f. The point ‘A’ in the line-scan denotes a Si-dimer, and the highest point in the profile ‘B’ corresponds to the midpoint of the molecular feature in this line. At this bias (−3V) the average height of the molecular feature with respect to the Si-dimer is 0.7 Å. The dark features in the STM images are due mainly to missing-dimer defects.

FIG. 2 shows scanning tunneling microscope (STM) images of single nanolines, a A high resolution image (50 Å×30 Å) of a single DCP line with a line height profile (inset) taken along the line X to X′; the circled feature ‘B’ is the perturbation at the end of the line due to surface buckling. b reproduces the image in a with ball and stick molecules superimposed, to scale, of (DCP)₂ and DCP over the corresponding features of the image. c-f STM images (85 Å×60 Å) of a further single DCP line at negative and positive voltages; left and right pairs of images were recorded simultaneously. The white lines A-A′ and B-B′ marked in each image represent the same features, the ridges of adjacent dimer rows in b to d. In positive bias the DCP line always appears bright relative to the dimer rows. The positive bias images, c and e show the well-known contrast reversal at and above +1.5 V bias; A-A′ and B-B′ thereupon appear as valleys rather than ridges. In negative bias images the DCP line appears dark relative to the dimer rows, brightening as the bias goes to larger negative values. The direction of growth of the lines is indicated by white arrows; line growth can be seen to begin with a DCP-dimer (DCP)₂. Dark ‘trenches’ are observed to both sides of the DCP lines of bright molecules; this is due to pinning of adjacent dimers (see text and FIG. 4). At high bias (positive and negative), the DCP dimers can be seen to be almost indistinguishable from individual DCP molecules. The white arrow, in each case, is the direction of line growth.

FIG. 3 is a schematic illustration of the mechanism of formation of the molecular-line (theory). a shows a schematic representation of the dipoles (short black arrows) responsible for buckling of the dimers. The locations of the molecules are represented by golden ellipses. The grey box represents the super-cell slab used for the calculation. The black dashed lines denote the center of the Si-dimer rows. The 1,5 DCP molecule and the colour-coded ‘up’ and ‘down’ Si dimer atoms are in the legend. b shows the ground state Si(100)−p2×2 surface. The dimer pairs are numbered 1A-1A′, 1B-1B′ and 1C-1C′ in the left dimer row, 2A-2A′, 2B-2B′ and 2C-2C′ in the adjacent dimer row and 3A-3A′, 3B-3B′ and 3C-3C′ in the third dimer row. The ‘up’ and ‘down’ dimers are colour coded red and green. c shows the computed buckling due to adsorption of a single molecule on row 1. The bonded Si-atoms 1B′ and 1C′ are down, while 1B and 1C are up. In row 2, 2B′ and 2C′ are up, 2B and 2C are down. The brackets indicate favored pairs of adsorption sites for the second DCP molecule. d shows attachment of the second molecule in row 2 repeats for rows 2 and 3 the process of surface-buckling shown for rows 1 and 2 in c. The third adsorbate molecule (not shown) will attach to the bracketed Si-atoms collinear with the first two dipolar adsorbate molecules. e shows charge re-distribution on adsorption of a DCP molecule. (i) Loss (L) in electronic-density within white contour shown (−0.004 ē/Å³), and (ii) gain (G) in electronic density within white contour (+0.004 ē/Å³). Colour coding as before; Cl indicates approximate location of the halogen atom losing negative charge, and DB the location of the Si dangling bond (1B and 1C) gaining charge. The black dashed line denotes the center of the Si dimer row.

FIG. 4 shows a comparison between theoretical and experimental images: The Theory column shows simulated STM images, a and d, of DCP molecules arranged in lines on Si(100)−p(2×2) at a +0.6 V and d −0.6 V bias. Each rectangle in the grid represents a 2×1 unit cell (two of which are highlighted by a blue rectangle where up and down Si-atoms are colored red and green); DCP molecules are drawn to scale at the right in the simulated images. The centers of the dimer rows in the simulated images are indicated by dashed lines (corresponding to the ridge of the dimer rows in the experimental images). In the simulated image of the empty state, a, bright protrusions are visible at the location of the Cl atoms. The ‘Experiment’ column, b and e shows images recorded at the same bias as the simulations; the appearance of the lines in the simulated images matches well with the appearance of the lines in the experimental STM images at the same bias. For the positive bias image, theoretical simulations were made at half the experimental current (0.1 nA rather than 0.2 nA) consequently the features due to DCP appear enlarged relative to the experimental image. The ‘Experiment+Theory’ column shows overlays, panels c and f, of the simulated lines on top of the experimental images. The dark arrows X-X′ and Y-Y′ in d show a line of darkness above the molecular line and a line of brightness below the molecular line (see Detailed Description). The filled state STM image at −0.6 V is shown in e; the lines appear darker at this bias which matches the simulated image d.

A further understanding of the functional and advantageous aspects of the invention can be realized by reference to the following detailed description and drawings.

### DETAILED DESCRIPTION OF THE INVENTION

A method for the mask-free linear atomic- or molecular-patterning of crystalline surfaces by physisorptive or chemical self-assembly, is disclosed. The method for marking a surface on an atomic or molecular scale disclosed herein will be described and illustrated hereinafter using a non-limiting, illustrative example in which a crystalline silicon wafer is marked. However, it is to be understood by those skilled in the art that the invention is in no way limited to this system but rather the silicon system serves only to illustrate the principles of the present invention.

The line is initiated by ‘perturbation’ of one or more atoms at the underlying surface through dosing the solid surface with a measured amount of the gaseous material from which part or all of the line is to be formed. Such dosing results in physisorptive or chemical bonding to or near a restricted number of surface atoms at which the line or lines will originate. This initial perturbation is due to charge-transfer to or from the surface as a result of the physisorptive or chemical attachment of the initiator atoms or molecules dosed on the surface. This initial charge-transfer induces a surface dipole vector at the site of each newly-attached atom or molecule.

The aforementioned charge-transfer at the site of each newly-attached atom or molecule has the valuable consequence of resulting in ‘localised doping’, enhancing the electrical conductivity of the underlying semiconductor surface. When the charge-transfer is to the surface this is localized n-type doping (added electrons), when it is away from the surface it is localized p-type doping (added ‘holes’), in either case giving rise to more charge-carriers in the region of the physisorbed or chemisorbed atoms or molecules that comprise the self-assembled line. As a consequence the lines herein described act as charge-carriers, i.e. they constitute ‘nano-wires’.

The effect of this vectorial charge-transfer is to alter the inter-atomic forces in the substrate locally, thereby introducing a strain in the surface originating in the newly attached atoms or molecules, propagating in a preferred direction relative to the charge-transfer vector (directly opposite to that vector in the examples cited). This initial charge-transfer-induced strain has the effect of a local surface-expansion or contraction, directed with respect to the charge-transfer vector. This strain relieves itself by buckling adjacent atoms at the surface, in the preferred direction noted above. This directed propagation of strain by surface buckling (surface-atom displacement) is a key feature in the method disclosed herein for the self-assembly of lines at crystalline surfaces.

Additionally, crystalline surfaces exhibit preferred linear directions for the relief of strain along crystal symmetry-axis', due to the same weakness that causes crystals to ‘cleave’ along these axis'. Buckling (i.e. strain-relief) directed at an adjacent atomic site to the initial perturbation takes place, therefore, in a direction governed by the initiating surface-charge-transfer but preferentially along a crystal axis. The effect of the buckling caused by the initial charge-transfer perturbative event is to alter the electronic charge at the adjacent buckled (i.e. displaced) surface atom, thereby affecting the heat of adsorption for physisorptive attachment at that adjacent site, or the activation energy for reaction at that site, for a second adsorbate atom or molecule impinging randomly from the gas and encountering that site. Preferential adsorption or reaction of the dosed gaseous species at a buckled surface site constitutes a second key feature in the present method. This preferential adsorption or reaction results in the growth of a directed line of adsorbate atoms or molecules at the surface, since each adsorptive or reactive event causes a local charge-transfer to or from the surface with adjacent surface buckling in a preferred direction.

Though it would be sufficient for the working of the present method that the initial perturbation result in an extended directed line of buckled surface atoms (that would then capture a line of atoms or molecules by adsorption or reaction), such long-range buckling is not necessary. What is required, instead, is that the initial perturbation due to adsorption or reaction cause buckling at a single adjacent surface atom. The adjacent buckling (termed the ‘first’ buckling) has the consequence that a second adsorbate molecule impinging at the surface adsorbs and/or reacts chemically at this first-buckled surface site, due to the buckled site's modified charge-cloud.

The sequential process of adsorption, adjacent-buckling, and capture of a further adsorbate at the adjacent buckled site with immediate or subsequent chemical reaction, is responsible for line-propagation. Exemplifying this sequence that leads to line-formation by a further stage, the attachment of a second adsorbate atom or molecule, described above, results in a further directed charge-transfer to/from the surface and hence a ‘second’ directed surface-buckling event adjacent to that second molecule, and hence in the capture and/or reaction of a third impinging atom or molecule thereby propagating the line to that third atom or molecule.

The physisorbed or chemisorbed line formed in this fashion by sequential adsorption/reaction at a buckled surface atom followed by further directed adjacent buckling can terminate due to the ending of sequential adsorption owing to lack of further adsorbate molecules, or alternatively due to termination of the adsorption-plus-adjacent-buckling sequence because of a defect at the surface along the line of propagation that diminishes buckling to the extent that the next atom or molecule impinging on the surface fails to be captured.

It is evident that by changing the nature of the gas being dosed the atom or molecule used to initiate the line may be of the same or different type from the atom or molecules used to propagate the line. The atom or molecule used for propagation may be a single chemical species or differing species, and the initiating and or propagating species may be applied sequentially or as a mixture. Different species may be used to control line growth in different directions upon the surface, since the chemical properties of the adsorbate determine the direction of the charge-transfer vector at the surface due to adsorption or reaction, and consequently the location of the adjacent buckling responsible for line-growth.

The dosing gas comprises atoms or molecules that induce charge-transfer locally, to or from the crystalline substrate, causing the substrate to become electrically conducting locally beneath the atomic or molecular line, thereby constituting a self assembled nanowire.

The atoms or molecules of the dosing gas may be selected such that the atoms or molecules are physisorbed in the lines, and the method may include inducing localized chemical attachment to the surface of the substrate atoms or molecules by any one or combination of heating the substrate surface, bombarding the substrate surface with light, bombarding the substrate surface with electrons, or bombarding the substrate with other charged particles, as disclosed in Polanyi et al., U.S. Pat. Nos. 6,156,393, of Dec. 5, 2000; 6,319,566 of Nov. 20, 2001; and 6,878,417 of Apr. 12, 2005), all of which are incorporated herein by reference in their entirety.

The method of mask-free linear atomic- or molecular-patterning of crystalline surfaces by physisorptive or chemical self-assembly, of the present invention will now be illustrated by the following non-limiting example.

### EXAMPLE

### Dipole-induced Assembly of Lines of 1,5-Dicholoropentane by Displacement of Surface Charge in Si(100)

In this example, physisorbed 1,5 dichloropentane (DCP) on Si(100)−2×1 at room temperature is shown by scanning tunneling microscopy (STM) to self-assemble into molecular lines that grow predominantly perpendicular to the Si-dimer rows. Extensive simulations indicate that the trigger for formation of these lines is the displacement of surface charge by the dipolar adsorbate, giving rise to an induced unidirectional surface-field and hence surface buckling in the opposite direction to the DCP adsorbate molecular dipole. Close agreement between experimental and simulated STM images is reported for DCP on a Si(100)−2×1 surface for a range of bias voltages in both filled and empty states. The geometry of the physisorbed molecules at the surface and nature of their binding is evident from the STM images, as interpreted by STM simulations.

One-dimensional nanostructures at silicon surfaces have potential applications in nano-scale devices, particularly in nanoelectronics, which necessitates non-lithographic ways of creating interconnects at the nanometer scale. Over the last decade many systems have been identified that yield self-assembled atomic or molecular lines on semiconductors. The two-step approach to nanofabrication being explored by the inventors is (a) patterned physisorption of intact molecules, followed (b) by the patterned chemisorbed imprinting of halogen atoms through ‘localized reaction’^{1, 2} induced by electron- or photon-irradiation.

Bismuth nanolines^{3, 4, 5, 6, 7, 8} and rare-earth silicide nanowires^{9, 10, 11, 12, 13, 14, 15, 16, 17, 18} on Si(100)−2×1 have been studied by STM. These lines, of up to 500 nm in length, grow perpendicularly to the Si-dimer rows. The lines are formed at high substrate temperatures, around 600° C., by sub-surface reconstruction induced by covalent bonding. Shorter nanolines formed on Si(100) from group II, III and IV metals (e.g. Mg, Al, Sn) have also been reported^{19, 20, 21, 22, 23, 24, 25}.

Chemical chain-reactions have been used to grow nano-lines^{26, 27, 28, 29, 30}. Growth occurred along^{26, 27, 28} and across^{29, 30} the dimer rows of H-terminated Si(100), initiated from a dangling-bond site^{26, 27, 28, 29, 30}. Recently, self-assembled molecular lines were formed on a bare Si(100)−2×1 surface perpendicular to the dimer rows³¹, using a surface chain-reaction initiated by pyrazine.

All these nano-lines were formed as a result of covalent bonding within or at the surface. Lines of physisorbed molecules have been self-assembled through inter-molecular hydrogen-bonding on smooth graphite³² and metal surfaces³³, but not on Si(100). We describe a method for the formation of self-assembled molecular lines at room temperature on a bare Si(100)−2×1 surface using the novel approach of ‘Dipole-Induced Assembly’ (DIA) exemplified here by 1,5 Dichloropentane and in forthcoming work by 1-Chloropentane, 1-Fluoropentane, and 1-Chlorododecane.

The adsorbate is shown by ab initio calculation to result in a dipole at the surface and to induce buckling of the Si dimer-pair of an adjacent row. This buckling favors adsorption of a molecule at the buckled site. The second adsorbate molecule induces a further buckling in the next Si-dimer row and hence a new site favoring molecular adsorption, and so on, thereby propagating a line of intact physisorbed molecules, as observed. The direction of line growth is invariably opposite to the direction of the dipole. The predominant uni-directionality of line-growth is not explained ab initio; it is likely to have its origin in the tendency for the relief of surface-strain to take place linearly along an axis of symmetry (see for example:^{34, 35, 36, 37}).

The present example involves the case of 1,5-dichloropentane (DCP), studied at a clean room-temperature Si(100)−2×1 surface by STM. This molecule was chosen since the Cl . . . Cl separation in one configuration is approx. 4 Å, closely matching the 3.8 Å Si . . . Si separation between adjacent Si-dimer pairs, hence offering the possibility of physisorption in a bridging configuration with the Cl atoms located over adjacent Si-atoms.

The observations are interpreted by DFT calculations. According to both theory and (STM) experiments, the DCP molecules physisorbed at room temperature with their terminal Cl-atoms interacting with adjacent Si-dimer atoms to one side of the same dimer-row (i.e. asymmetrically). The DCP molecular lines self-assembled uni-directionally in the direction of their asymmetric point of attachment, and hence opposed to the direction of the C—Cl dipoles. The direction of line growth was predominantly perpendicular to the dimer rows.

Simulations matched the STM images closely for both empty and filled-state (positive and negative surface bias) images. Comparison of the STM images with the simulations yielded the adsorption geometry of the molecules and hence the origin of the likely physisorptive interactions, C—Cl . . . Si, binding the DCP to Si atoms at the underlying surface.

A recent theoretical study^{38, 39} of the interactions of dipolar molecules with Si(100)−2×1 at high coverages of 0.5 and 1.0 monolayers predicted four types of important surface effects resulting in a preference for molecular absorbtion on neighboring silicon dimers of the row. However, these workers discounted the possibility of interaction between the adjacent dimer rows, central to the present Example.

### METHODS

### a) Experimental Methods

Experiments were carried out at room temperature in UHV with the aid of two STM instruments (RHK400 and Omicron-VT) using phosphorous doped (n-type, 0.01-0.02 Ωcm, 250±25 μm in thickness) Si(100) reconstructed to give Si(100)−2×1. The adsorbate 1,5 dichloropentane (99.9% pure, from Aldrich) was subjected to repeated freeze-pump-thaw cycles before being introduced to the UHV chamber through a leak valve for background dosing. Exposures are reported in Langmuir (1 L=1×10⁻⁶ Torr s) measured at an uncorrected ion-gauge calibrated for N₂. The corrected doses would be ˜10× lower than the stated doses⁴⁰. The STM tips were made by a DC electrochemical etch of polycrystalline tungsten wire in a 2M NaOH solution.

The STM's were operated in the constant-current mode. All measurements were made with a tunneling current of 0.2 nA. Samples were cleaned in UHV by several cycles of direct current heating to 1240° C. for ˜1 min. The STM images of the surface cleaned in this way showed a (2×1) reconstruction and <0.2% of surface defects.

### b) Electronic Structure Simulations

The ground state electronic structure of one or two molecules on Si(100) was simulated with the Vienna ab-initio simulation package (VASP)^{41, 42}, using ultrasoft pseudopotentials and the PW91 parameterization⁴³ of the exchange-correlation potential. The Si(100) slab contained 8 layers, the bottom layer of which was passivated with hydrogen. We simulated a 4×4 and a 4×6 super-cell, retaining the p(2×2) arrangement of the buckled dimers. The high number of layers was necessary to represent the high elasticity of the silicon lattice. Due to the large number of atoms we limited the simulations of the relaxed geometry to one k-point at the center of the surface Brillouin zone. The molecular adsorption site was determined by placing the bent molecules about 3 Å above the surface plane, with the molecular backbone parallel to the surface. The molecule as well as three surface layers were then fully relaxed until the forces on individual ions were less than 0.02 eV/Å.

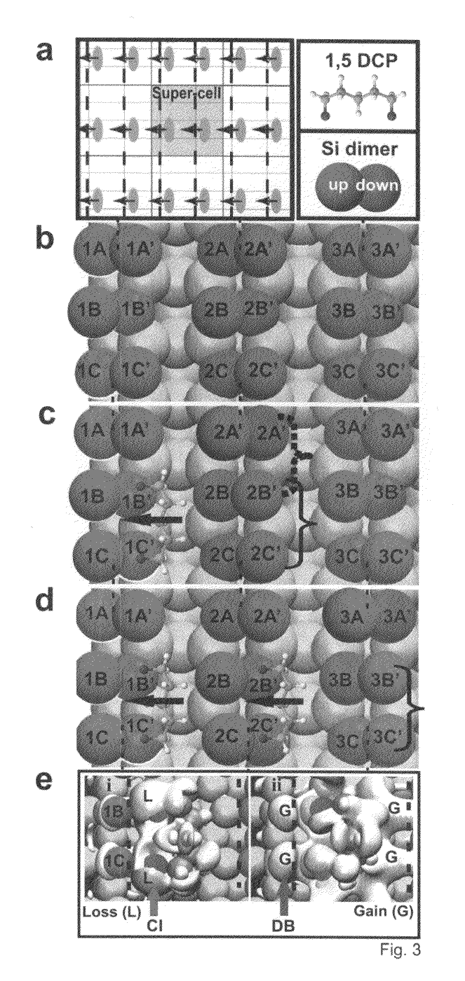

The molecular adsorption sites for one and two monomer DCP molecules in a 4×4 and 4×6 Si(100) super cell were calculated using. several super cells: a single DCP molecule in a 4×4 super cell, two molecules in alignment perpendicular to the dimer rows, two molecules in diagonal alignment, and the same arrangement of molecules in a 4×6 super cell. The alignment of adsorbate molecular dipoles is shown schematically in FIG. 3a. The grey box represents the super-cell slab used for the calculation (not the surface unit cell).

### c) Calculation of Dipoles

DFT calculation gives zero dipole for the symmetric linear DCP molecule in the gas. The dipoles were calculated for a single molecule on the Si(100)−4×4 super-cell using the dipole corrections implemented in our electronic structure code. For this simulation we first calculated the electron density of the molecules in the vacuum, then the density of the clean Si-surface and finally the density of the complete system. Subtracting the density of the components from the density of the complete system yielded the charge transfer due to adsorption. The position of the dipole was subsequently placed at the median position between positive and negative charge accumulation, and the dipole moment was calculated using dipole corrections in (only) two dimensions along the surface plane. We found a dipole moment of 4.85 Debye per molecule perpendicular to the dimer rows.

### d) Simulation of STM Images

The STM images for a current of 200 pA (negative bias) or 100 pA (positive bias) and a range of bias voltages were simulated using the electronic structure of the converged system, and the multiple scattering approach implemented in bSKAN^{44, 45}. To improve the accuracy we used a k-point set of 3×3 special k-points in the final electronic structure simulations, as also for the STM simulations. To obtain a closed contour surface in the simulation, the current value in the positive bias regime has to be reduced.

### Results and Discussion

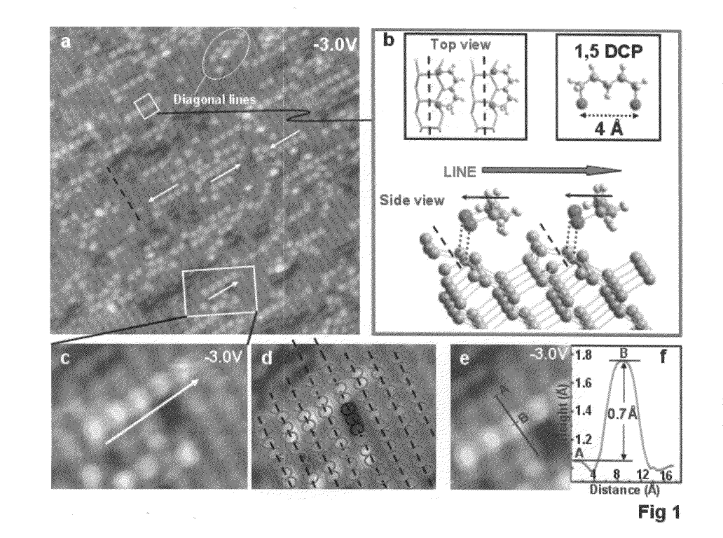

FIG. 1a shows an STM image of a Si(100)−2×1 exposed to 1 L (uncorrected) of 1,5-dichloropentane (DCP) at room temperature. Intact molecules physisorbed onto the Si surface and self-assembled to form lines predominantly perpendicularly to the dimer rows. Approximately 5% of the lines grew diagonally.

The molecule-molecule separation distance was 7.7 Å, in registry with the long-axis of the Si(100)−2×1 unit cell. The nano-lines consisted of 4-6 molecules on average; 40-50 Å long and 4 Å wide. Lines were, however, observed with up to 12 molecules (90-100 Å). Increased line length required low dose rates (see below). The STM images suggest that the individual DCP molecules change their C—Cl bond direction under the influence of the surface to align their chlorine atoms with two Si dimer-atoms, one from each adjacent dimer pair to one side of a dimer-row as shown in FIG. 1b. The width of the DCP-lines is comparable with the dimer-dimer distance along a row, namely 3.8 Å. This structure was confirmed by the ab initio calculations presented below.

The bright features characteristic of the physisorbed molecules did not bridge the dimer rows (FIGS. 1c and 1d). This is in contrast to the molecular lines formed by pyrazine on bare Si(100)−2×1 midway between two dimer rows since the pyrazine adsorbate was bound covalently to the adjacent rows³¹. The DCP-lines have an experimental height of 0.7 Å for −3 V (see FIG. 1f). This accords with the simulation which gives protrusions of ˜0.8 Å in the density contour for this voltage.

The DCP molecules involved in DIA physisorbed and self-assembled intact. The evidence for physisorption of intact DCP was that the molecular lines desorbed at elevated temperature (>˜200° C.) leaving no residue at the surface. In contrast, a covalently-bound Si—Cl bond formed by reaction at the surface will desorb only above 500° C.^{46, 47, 48}. Further, DCP molecular lines were thermally stable up to approx. 200° C. Above 200° C., over time, a fraction underwent reaction severing a C—Cl bond to give Cl—Si at the surface, characterized by circular bright spots in the STM image. The bright spots were the Si dangling-bonds adjacent to a reacted Cl (Cl—Si). The remainder of the DCP adsorbate desorbed from the surface at 200° C. without chemical reaction leaving no residue, as expected for a physisorbed molecule.

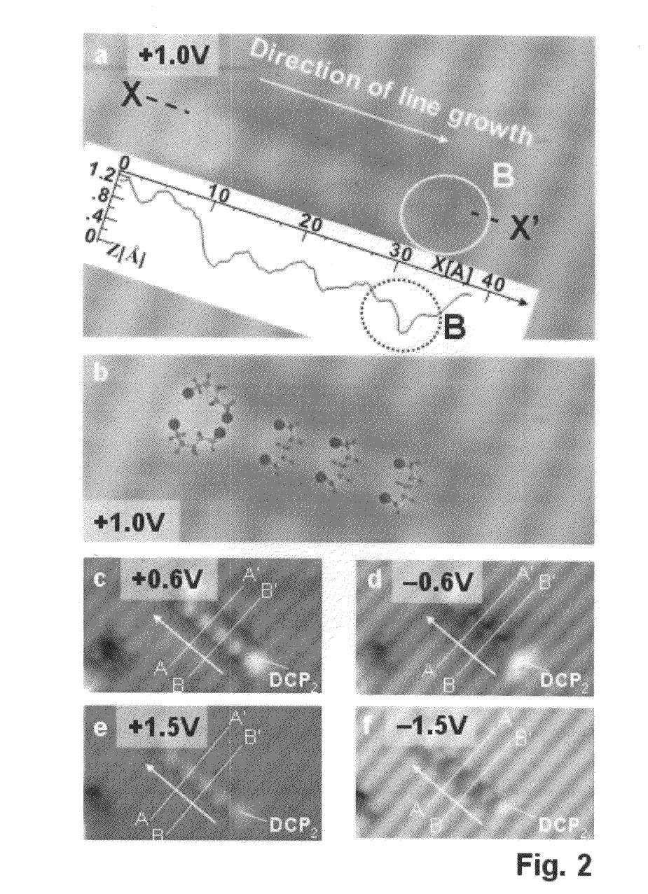

As noted, higher dose-rates gave shorter lines, lower dose-rates longer lines: dosing at 1×10⁻⁹ Torr produced lines of 8-10 molecules, whereas 1×10⁻⁸ Torr gave lines of 3-5 molecules. The STM images indicated that the lines invariably originated in dimeric DCP, (DCP)₂, a characteristic large bright feature evident at the head of the line in FIG. 2. At the highest dose rate only this bright feature was observed.

Previously, we found that chloroalkanes on Si(111)−7×7 predominantly formed dimers at high dose rates, physisorbing horizontally on Si(111)−7×7 and Si(100)−2×1 in contact with the surface⁴⁹. This geometry gave additional binding from the contact of CH₂ with the underlying Si-surface, rendering the horizontal molecules more stable in their adsorbed state^{50, 51, 52}. The dimeric (DCP)₂ was found on heating, as expected from its multiple points of attachment, to be more strongly-bound to the surface than the monomer⁵¹.

In the present Example, line length was limited by a kinetic competition between (a) dimer formation—the start of a new line—and (b) attachment of monomer to an existing line resulting in line growth. Because of the quadratic dependence on monomer concentration for dimer formation⁵³, high dose rates favored the formation of many dimers, and hence shorter lines.

At room temperature, we observed no features that could be ascribed to single monomeric DCP molecules in the adsorbed state, due, presumably, to their high mobility. The observed molecular lines originated in a stable (DCP)₂ dimer—the ‘anchor’ for that line. The lines propagated through linear self-assembly of a succession of DCP monomers which, though unstable individually, were highly stable when self-assembled, even at elevated temperatures to ˜200° C. At high resolution the lines in the room temperature images gave evidence of terminating in a raised surface feature (see FIG. 2), in accord with expectation from the DIA model, presented in the following sections.

In other experiments DCP was dosed at a 100° C. Si(100)−2×1 surface using the same dose rate as in the room temperature experiments. No nanolines were observed. Instead reaction took place to yield exclusively halogen atoms. Once again, the remainder of the DCP molecule desorbed. Dosing at 100° C. gave a smaller coverage, in this case of Cl—Si, by a factor of ×10-12, than an equivalent dose at room temperature, indicating that the sticking probability was lower by this amount as compared with that at room temperature.

In FIG. 2(a) we show a high resolution image of a single DCP line. The ‘anchor’, DCP-dimer, (DCP)₂, is clearly visible, as are the individual DCP molecules in the line, and also the Si-surface dimers and back-bonds. The end of the line shows a severe perturbation of the Si dimers. Theory suggests that this perturbation is due to buckling of the surface originating in the dipole of the adsorbate (hence ‘Dipole Induced Assembly’) encouraging the adsorption of a further DCP molecule and thereby continuing line-growth. Line-growth is limited here by DCP coverage.

FIGS. 2(b) to 2(e) shows STM images of another DCP line, obtained with different negative and positive sample biases (at left and right, respectively). The appearance of the line can be seen to be highly voltage-dependent. The corresponding left and right images were taken simultaneously with opposite biases in alternate line scans.

In the filled state (negative surface bias) images (b) and (e) at the left, as the magnitude of bias was increased the lines brightened. At sufficiently high negative bias, starting at −2V (not shown), the molecular lines were brighter than the Si-dimer rows; at lesser negative biases they appeared darker than the Si-dimer rows. The bright features comprising the lines of DCP in the STM images are calculated to be primarily due to the contribution from the alkyl chains made visible by the attached halogen atoms^{54, 55}. Images (c) and (e) give the well known contrast reversal, in which the ridge of a dimer row appears bright below 1.5 V and dark above 1.5 V surface bias^{56, 57, 58}.

### DFT Calculations

In order to understand the formation of molecular lines on the surface we performed extensive DFT simulations (see Methods). In FIG. 3 a to e we show the details of the computed mechanism for line-propagation. The second panel, b, shows the state of the Si-dimers p(2×2) on Si(100), which is in an unperturbed up-down Si-dimer pair configuration. The up and down Si-atoms in the Si-dimers are colour coded red (up) and dark green (down) as shown in the legend (top panel). Generally this configuration corresponds to an excess (up) and a depletion (down) of electron charge⁵⁹. The two Si-dimer pairs of interest, on which the Cl-atoms of the first DCP will physisorb, are labeled 1B′ and 1C′.

The adsorption energy using a linear molecule in vacuum as the reference is 2.6 eV per molecule. The energy required to change the C—Cl bond direction from that in the gas phase molecule to the configuration on the surface is approximately 0.2 eV. Calculation of a DCP dimer clearly showed buckling of the adjacent Si dimer-pair, as for DCP monomer. Details of (DCP)₂ interaction with the surface will be published as a part of a study of dimeric adsorbates and their Dipole Induced Assembly.

The present discussion focuses on the (novel) mechanism of DCP monomer line-propagation. The attachment of a single DCP molecule at 1B′ and 1C′ on row #1 leads to a dipole, due both to charge transfer from the Cl-atoms of DCP to adjacent Si-dimers plus the induced dipole of the molecule in its adsorbed configuration. This net dipole is directed perpendicular to the Si-dimer rows with a dipole strength of 4.85 Debye indicated by black arrows in FIG. 3 (we use the convention that the arrows point from positive to negative in the dipole). FIG. 3(c), shows buckling of the Si-dimers consequent on the adsorption of this first molecule. The computed charge re-distribution consequent on DCP physisorption is shown in FIG. 3e; electron density has moved from the Cl atoms (adsorbed at Si-atoms 1B′ and 1C′) to the other Si-atoms of the same dimer pairs, 1B and 1C, which, consequently, are raised to the ‘up’ configuration (see previous paragraph). Due to electrostatic interaction between the dipole and the Si-atoms of the adjacent row, #2 in FIG. 3, dimers 2A, 2A′; 2B, 2B′ and 2C, 2C′ flip as shown in FIG. 3c. This may be assisted by the inter-row charge-transfer evident as ‘tails’ in the negative charge gain (G) at the right of FIG. 3e (ii). The Si-dimer reorientation leads to an energy gain of 140 meV and provides a preferential adsorption site for the next molecule in its mobile precursor state.

The second DCP molecule can only attach at the elevated Si-atoms (2B′, 2C′) due to steric hindrance from the first DCP. Subsequently the pair of Si-atoms, 2B′, 2C′, move down (FIG. 3d, green). This is accompanied by further reorientation at the adjacent Si-dimer row #3, with elevation of Si-atoms 3B′ and 3C′, preparing a raised site for attachment of a third DCP (FIG. 3d, red bracketed atoms). The sequence then continues until the system either runs out of adsorbate or encounters a defect.

A second DCP molecule migrating across the surface could, alternatively, (FIG. 3c) attach at the pair of Si-atoms labeled 2A′ (raised) and 2B′ (depressed). A growth direction perpendicular to the dimer rows is energetically favored due to dipole interactions by about 80 meV per molecule relative to diagonal line-growth. The difference in the adsorption energy is sufficient to make diagonal growth only ˜5% as likely as perpendicular growth, at room temperature, as observed.

In the presence of two adsorbate molecules (FIG. 3d) line-growth in general proceeds collinearly with these molecules, i.e. the lines rarely ‘wander’ from their initial propagation direction. A likely explanation is a tendency for strain to relieve itself linearly in the surface^{34, 35, 36, 37}. However, the growth of the line beyond two DCP molecules is beyond the limit of our super-cell, and hence not calculable.

In sum, adsorbed molecules induce substantial dipoles shown as black arrows pointing to the left in FIG. 3a, which result from charge-transfer to the surface and the dipole of the distorted DCP. Electrostatic interactions with this net dipole pin the Si-dimers on the adjacent Si-dimer row, to the right in the figure, into their new configuration as detailed above, and propagate the line through self-assembly of additional DCP monomer molecules away from the direction of the initial induced dipole. This is the mechanism for Dipole Induced Assembly (DIA).

### STM Simulations

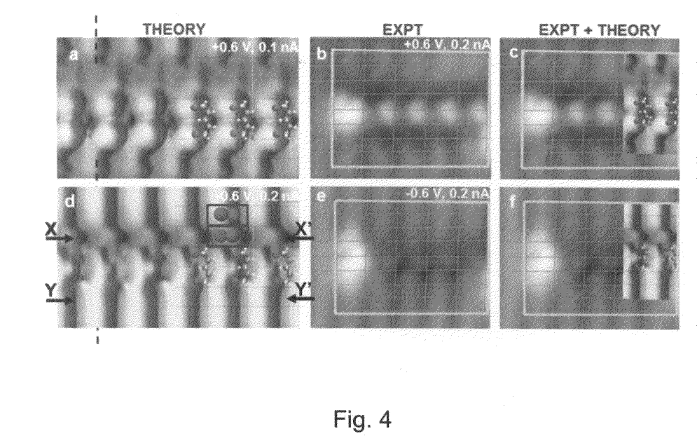

In FIG. 4 we compare the simulated STM image with the experimental constant-current (0.2 nA) STM images at a sample bias of ±0.6 V. The calculated images reproduce observation for a tip-surface distance of 6-7 Å. Images were simulated using a metal tip with a mono-atomic apex at a current of 0.2 nA (negative bias) and 0.1 nA (positive bias). The current contour in the positive regime is closer to the surface, we therefore had to decrease the contour value to obtain a closed contour surface (see Methods). Since the 4×4 super-cell is too small to describe the boundary between the molecular lines and the dimer rows, we used a 4×6 super-cell in all simulations. To analyze the effect of dimer buckling adjacent to the molecular rows we varied the super-cell boundary. The Si-dimers have the correct up-down orientation on one side (above, in the simulation of FIG. 4) but are flipped in the opposite direction on the other side (below, in the simulations of FIG. 4). At higher negative bias voltages (images not shown) we find that the protrusion due to the adsorbed molecules had its maximum at the position of the Cl-atoms.

The computed images in FIG. 4(d) have darkness above the molecular line (X-X′) and brightness below (Y-Y′). The calculated darkness is due to the Si-dimer being buckled in the opposite sense to the rest of its row, as shown in the blue-bounded insert. Brightness indicates that the Si-dimer is buckled in the same sense as the rest of its row. Experimentally, in both positive and negative STM images at low bias (±0.6 V; FIGS. 3b and 3e), we observe darkness at both sides of the line. It would appear that the dimers on both sides of the molecular rows are pinned, while the rest of the rows appear bright due to averaging of dimer positions at room temperature.

### CONCLUSIONS

The invention disclosed herein provides a novel Dipole-induced Assembly (DIA) mechanism for the formation of physisorbed molecular lines at room temperature on a Si(100)−2×1 surface, as observed by STM and modeled by DFT calculation. Self-assembly resulted in lines of intact 1,5-dichloropentane (DCP monomers) of up to 12 molecules aligned predominantly perpendicular to the dimer rows, with a 5% minority at a 26 degree angle to the rows. Once a pair of molecules established a line-direction, that direction was generally observed to be maintained, invariant for all subsequent molecules in the line.

The mechanism of line-propagation of DCP monomers was shown by DFT calculation to originate in the dipole of an adsorbed molecule; molecule 1, attached by its two halogen atoms to adjacent Si-atoms along a dimer-row. The dipole induced charge-transfer in the surface, perpendicular to the Si-dimer row. This transfer of charge resulted in buckling of adjacent dimer-pairs in row 2, giving rise to an attractive site for molecule 2. A second DCP monomer adsorbed adjacently with the first, further shifting the surface-charge, thereby buckling row 3 and capturing a third DCP molecule along the extension of the line formed by the first two so as to propagate the line.

At room temperature DCP monomers are mobile on Si(100)−2×1. Line-growth originated in a single dimer of (DCP)₂ (the ‘anchor’) through subsequent collinear assembly of the mobile DCP-monomers. In the STM images the constituent DCP molecules of the line were displaced to the same side of successive Si-dimer rows as the direction of line growth, in accord with theory. This direction of line-growth by DIA is opposite to the direction of the individual DCP dipoles. Where line-growth was limited by coverage, surface-buckling could be seen by STM in the Si dimer-row beyond the final DCP molecule of the line. Line-termination was also observed to occur due to defective assembly, occasioned by a second dimer or by a surface defect.

Without being limited by any theorem, the inventors believe that a requirement for Dipole-Induced Assembly (DIA) is that the initial adsorbate molecule has a preferred adsorbate alignment on the surface and a dipole moment when adsorbed. This preferred adsorbate alignment is determined by the interaction between adsorbate and substrate to give a dipole at the point of adsorption. The dipole causes surface buckling which propagates the line of adsorbate.

The adsorbate dipole, through the mediation of surface charge-transfer, is opposite to the propagation-direction of the self-assembled line. Further requirements are that the substrate be electrically polarizable, and that subsequent molecules to the first be sufficiently mobile to self-assemble. Charge-transfer in the surface manifests itself, in the present case, as a buckling of the silicon atoms of an adjacent dimer row of Si(100)−2×1.

The charge displacement at the site of adsorption causes buckling that then propagates linearly if the substrate is a crystal and has linear cleavage planes (as is common in crystalline solids). The inventors have grown atomic/molecular lines using a substantial range of different organic halides, and based on scientific understanding the present invention is not limited to organic halides. For example, the requirement for charge-transfer (to or from the surface) at the point of attachment of the adsorbate is also widely met by numerous classes of molecules, since this is the fundamental reason that adsorbates adhere to substrates.

While the above-mentioned charge-transfer gives rise to a local dipole moment, and in some, but not all, cases the direction of this dipole will determine the direction of propagation of strain (hence buckling) at the surface, hence the method disclosed herein uses dipole induced assembly (DIA), meaning that the dipole triggers the line-formation, but may not fully dominate the direction of propagation (since the nature of the surface must be factored in).

The physisorbed dipolar molecular lines observed in this work were stable up to temperatures of ˜200° C., without desorption or chemical reaction. The finding that mobile dipolar adsorbates can self-assemble into such robust lines under the influence of charge-transfer to or from the substrate should be of interest in contexts ranging from nanoscale electronics to molecular biology.

Thus the present invention has utility in a great number of areas, most particularly in design of molecular scale circuitry on surfaces. The method may be used with any type of crystalline surface and is not restricted to the molecules used in Example 1.

As used herein, the terms “comprises”, “comprising”, “including” and “includes” are to be construed as being inclusive and open ended, and not exclusive. Specifically, when used in this specification including claims, the terms “comprises”, “comprising”, “including” and “includes” and variations thereof mean the specified features, steps or components are included. These terms are not to be interpreted to exclude the presence of other features, steps or components.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

### REFERENCES

¹ Dobrin, S, Lu, X., Naumkin, F. Y., Polanyi, J. C., Yang, J (S. Y.) Imprinting Br-Atoms at Si(111) from a SAM of CH₃Br(ad), With Pattern Retention, Surf Sci. Lett. 573 L363-L368 (2004).
² Dobrin, S et al, Maskless nanopatterning and formation of nanocorrals and switches, for haloalkanes at Si(111)−7×7, Nanotechnology, 18, 044012 (2007).
³ Naitoh, M., Shimaya, H., Nishigaki, S., Oishi, N. & Shoji, F. Scanning tunneling microscopy observation of bismuth growth on Si(100) surfaces. Surf Sci. 377-379, 899-903 (1997).
⁴ Naitoh, M., Shimaya, H., Nishigaki, S., Oishi, N. & Shoji, F. Scanning tunneling microscopy observation of Bi-induced surface structures on the Si(100) surface. Surf Sci., 482-485, 1440-1444 (2001).
⁵ Owen, J. H. G, Miki, K. & Bowler, D. R. Self-assembled nanowires on semiconductor surfaces. J. Material Sci. 41, 4568-4603 (2006).
⁶ MacLeod, J. M. & McLean, A. B. Single 2×1 domain orientation on Si(100) surfaces using a periodic Bi line arrays. Phys. Rev B. 70, 41306 (2004);
⁷ MacLeod, J. M., Miwa, R. H., Srivastava, G. P. & McLean, A. B. The electronic origin of contrast reversal in bias-dependent STM images of nanolines. Surf Sci., 576, 116-122 (2005).
⁸ Preinesberger, C., Vandre, S., Kalka, T. & Dahne-Preitsch, M. Formation of dysprosium silicide wires on Si(001). J Phys. D. 31, L43 (1998).
⁹ Chen Y., Ohlberg, D. A. A., Williams, R. S. Nanowires of four epitaxial hexagonal silicides grown on Si(001). J. Appl. Phys. 91, 3213-3218 (2002).
¹⁰ Nogami, J., Liu, B. Z., Katkov, M. V., Ohbuchi, C. & Birge, N. O. Self-assembled rare earth silicide nanowires on Si(001). Phys. Rev. B 63, 233305 (2001).
¹¹ Liu B. Z. and Nogami J. Growth of parallel rare earth silicide nanowire arrays on vicinal Si(001). Nanotechnology 14, 873 (2003).
¹² Liu, B. Z. & Nogami J. An STM study of the Si(001)(2×4)-Dy surface. Surf Sci. 488, 399-405 (2001).
¹³ Ohbuchi, C. & Nogami, J. Holmium growth on Si(001): surface reconstructions and nanowire formation. Phys. Rev. B 66, 165323 (2002).
¹⁴ Katkov, M. V. & Nogami, J. Yb and Nd growth on Si(001). Surf Sci. 524, 129-136 (2003).
¹⁵ Ohbuchi, C. & Nogami, J. Samarium induced surface reconstructions of Si(001). Surf Sci. 579, 157-165 (2005).
¹⁶ Harrison, B. C. & Boland, J. J. Real-time STM study of inter-nanowire reactions: GdSi₂ nanowires on Si(100). Surf Sci. 594, 93-98 (2005).
¹⁷ Evans, M. M. R. & Nogami, J. Indium and Gallium on Si(001): A closer look at the parallel dimer structure. Phys. Rev. B 59, 7644 (1999).
¹⁸ Nogami, J., Baski, A. A. & Quate, C. F. Aluminum on the Si(100) surface: growth of the first monolayer. Phys. Rev. B 44, 1415-1418 (1991)
¹⁹ Glueckstein, J. C., Evans, M. M. R. & Nogami, J. Growth of Sn on Si(001) at room temperature. Surf Sci. 415, 80-94 (1998)
²⁰ Itoh, H., Tanabe, H., Winau, D., Schmid, A. K. & Ichinokawa, T. Growth mode and surface structures of the Pb/Si(001) system observed by scanning tunneling microscopy. J. Vac. Sci. Tech. B 12, 2086-2089 (1994)
²¹ Tomatsu, K., Nakatsuji, K., Iimori, T. & Komori, F. STM observation of initial growth of Sn atoms on Ge(001) surface. Surf Sci., 601, 1736-1746 (2007)
²² Hutchison, P., Evans, M. M. R. & Nogami, J. Mg growth on the Si(001) surface: an STM study. Surf Sci. 411, 99-110 (1998)
²³ Bakhtizin, R. Z., Kishimoto, J., Hashizume, T. & Sakurai, T. STM study of Sr adsorption on Si(100) surface. App. Surf Sci., 94, 478-484 (1996)
²⁴ Bird, C. F. & Bowler, D. R. A spin polarized first-principles study of short dangling bond wires on Si(001). Surf Sci., 531, L351-L355 (2003).
²⁵ Chen, T. C. et. al. Atomic-scale desorption through electronic and vibrational excitation mechanisms. Science, 268, 1590-1592 (1995)
²⁶ Lopinski, G. P., Wayner, D. D. M. & Wolkow, R. A. Self-directed growth of molecular nanostructures on silicon. Nature 406, 48 (2000).
²⁷ DiLabio, G. A., Piva, P. G., Kruse, P. & Wolkow, R. A. Dispersion interactions enable the self-directed growth of linear alkane nanostructures covalently bound to silicon. J. Am. Chem. Soc. 126, 16048-16050 (2004).
²⁸ Kruse, P., Johnson, E. R., DiLabio, G. A. & Wolkow, R. A. Patterning of vinylferrocene on H—Si(100) via self-directed growth of molecular lines and STM-induced decomposition. Nanoletters 2, 807-810 (2002).
²⁹ Hossain, M. Z., Kato, H. S. & Kawai, M. Controlled fabrication of ID molecular lines across the dimer rows on the Si(100)−(2×1)-H surface through the radical chain reaction. J. Am. Soc. Chem. 127, 15030-15031 (2005).
³⁰ Hossain, M. Z., Kato, H. S. & Kawai, M. Fabrication of interconnected ID molecular lines along and across the dimer rows on the Si(100)−(2×1)-H surface through the radical chain reaction. J. Phys. Chem. B 109, 23129-23133 (2005).
³¹ M. Shimomura et. al. Formation of one-dimensional molecular chains on a solid surface: pyrazine/Si(001). Phys. Rev. B 72, 033303 (2005).
³² See for example, Cyr, C. M., Venkataraman, B. & Flynn, G. W. Functional group identification in scanning tunneling microscopy of molecular adsorbates. J. Phys. Chem. 100, 13747-13759 (1996).
³³ See for example, Canas-Ventura, M. E. et. al. Coexistence of one- and two-dimensional supramolecular assemblies of terephthalic acid on Pd(111) due to self-limiting deprotonation. J Chem Phys. 125, 184710 (2006)
³⁴ Y. Wang, X. Chen, and R. J. Hamers, Atomic-resolution study of overlayer formation and interfacial mixing in the interaction of phosphorus with Si(001). Phys. Rev. B 50, 4534-4547 (1994).
³⁵ L. Kipp, R. D. Bringans, D. K. Beigelsen, J. E. Northrup, A. Garcia, and L.-E. Swartz, Phosphine adsorption and decomposition on Si(100) 2×1 studied by STM. Phys. Rev. B 52, 5843 1995.
³⁶ J. Knall and J. B. Pethica, Growth of Ge on Si(100) and Si(113) studied by STM. Surf Sci. 265, 156-167 1992.
³⁷ Ch. Park, R. Z. Bakhizin, T. Hashizume, and T. Sakurai, Strain relief and ordering of (2×n)-Bi structure on Si(100). J. Vac. Sci. Technol. B 12, 2049 (1994).
³⁸ Wang, Y., Hwang, G. S., Two-dimension arrangement of CH₃NH₂ adsorption on Si(001)−2×1, Chem. Phys. Lett., 385, 144-148 (2004).
³⁹ Wang, Y., Hwang, G. S., Origin of nonlocal interactions in adsorption of polar molecules on Si(001)−2×1, J. Chem. Phys., 122, 164706 (2005).
⁴⁰ Bartmess, J. E., & Georgiadis, R. M. Empirical methods for determination of ion gauge sensitivities for different gases. Vacuum 33, 149-153 (1983).
⁴¹ Kresse, G., & Hafner, J. Ab initio molecular dynamics for liquid metals. Phys. Rev. B 47, 558-561 (1993).
⁴² Kresse, G., & Furthmüller, J. Efficient iterative schemes for ab initio total-energy calculations using a plane-wave basis set. Phys. Rev. B 54, 11169-11186 (1996).
⁴³ Perdew, J. P., Chevary, J. A., Vosko, S. H., Jackson, K. A., Pederson, M. R., Singh, D. J., & Fiolhais, C. Atoms, molecules, solids, and surfaces: Applications of the generalized gradient approximation for exchange and correlation. Phys. Rev. B 46, 6671-6687 (1992).
⁴⁴ Hofer, W. A., & Redinger, J. STM of binary alloys: first principles calculation of the current for PtX(100) surfaces. Surf Sci., 447, 51-61 (2000).
⁴⁵ Palotas, K., & Hofer, W. A. Multiple scattering in a vacuum barrier obtained from real-space wavefunctions. J Phys: Condens. Mat., 17, 2705 (2005).
⁴⁶ Gao, Q., Cheng, C. C., Chen, P. J., Choyke, W. J. & Yates, J. T. Jr. Chlorine bonding sites and bonding configurations on Si(100)−2×1. J. Chem. Phys. 98, 8308-8323 (1993).
⁴⁷ Szabo, A., Farrall, P. D. & Engel, T. Reactions of chlorine with Si(100) and Si(111): adsorption and desorption kinetics. Surf Sci. 312, 284-300 (1994).
⁴⁸ Gupta, P., Coon, P. A., Koehler, B. G. & George, S. M. Desorption product yields following Cl₂ adsorption on Si(111)−7×7: coverage and temperature dependence. Surf Sci. 249, 92-104 (1991).
⁴⁹ Dobrin, S. et. al. Self-assembled molecular corrals on a semiconductor surface. Surf Sci. 600, 43-47 (2006).
⁵⁰ Dubois, M., Delerue, C. & Rubio, A. Adsorption and electronic excitation of biphenyl on Si(100): a theoretical STM analysis. Phys. Rev. B 75, 041302 (2004).
⁵¹ Grandidier et. al. Effect of alkyl substituents on the adsorption of thienylenevinylene oligomers on the Si(100) surface. Surf Sci. 473, 1-7 (2001).
⁵² Lei, R. Z., Gellman, A. J. & Koel, B. E. Desorption energies of linear and cyclic alkanes on surfaces: anomalous scaling with length. Surf Sci. 554, 125-140 (2004) and references therein.
⁵³ Dobrin, S., Harikumar, K. R., Jones, R. V., McNab, I. R., Polanyi, J. C., Waqar, Z. and Yang, J. (S. Y.) Molecular dynamics of haloalkane corral-formation and surface halogenation at Si(111)−7×7, J. Chem. Phys. 125, 133407 (2006).
⁵⁴ Grandidier et. al. Effect of alkyl substituents on the adsorption of thienylenevinylene oligomers on the Si(100) surface. Surf Sci. 473, 1-7 (2001).
⁵⁵ Dubois, M., Delerue, C. & Allan G. Scanning tunneling microscopy and spectroscopy of conjugated oligomers weakly bonded to Si(100) surfaces: A theoretical study. Phys. Rev. B 71, 165435 (2005)
⁵⁶ Kondo, Y., Amakusa, T., Iwatsuki, M. & Tokomoto, H. Phase transition of the Si(001) surface below 100 K. Surf Sci. 453, L318-L322 (2000).
⁵⁷ Lyubinetsky, I., Dohnalek, Z., Choyke, W. J. & Yates, J. T. Jr. Phys. Rev. B 58, 7950-7957 (1998).
⁵⁸ Okada, H., Fujimoto, Y., Endo, K., Hirose, K. & Mori, Y. Detailed analysis of scanning tunneling microscopy images of the Si(001) reconstructed surface with buckled dimers. Phys. Rev. B 63, 195324 (2001).
⁵⁹ see for example, Oura, K., Lifshits, V. G., Saranin, A. A., Zotov, A. V., & Katayama, M. Surface Science. An Introduction. 181-183 (Springer-Verlag Berlin Heidelberg New York, 2003)

Therefore what is claimed is:

1. A method of mask-free linear atomic- or molecular-patterning of crystalline surfaces by physisorptive or chemical self-assembly, comprising the steps of:
a) an initiation step including exposing a surface of an electrically polarizable crystalline solid with a gas of initiator atoms or molecules selected to attach to said surface at an initiator site and having a property of inducing a charge-displacement, hence a dipole moment, at a point of attachment at the initiator site with resultant local displacement of a surface atom or atoms at that site, giving rise to surface-strain and hence surface ‘buckling’ at that initiator site, which buckling propagates along a crystal axis causing buckling at least one adjacent site along that axis, and
b) following the initiation step, exposing the surface to a dosing gas containing atoms or molecules that bathe the surface, which dosing gas may have the same chemical composition or different chemical composition from the initiator gas, but which atoms or molecules of the dosing gas are sufficiently mobile to self-assemble and which are attracted to the aforementioned buckled site or sites adjacent to the initiator site so that a line originating from the initiator site “propagates’, sequentially, an atom or a molecule at a time, each atom or molecule once more causing charge-displacement and adjacent buckling so that a line grows away from the initiator site by accretion of physisorbed or chemisorbed atoms or molecules from the gas.

2. The method according to claim 1 wherein a particular surface of the crystalline solid is selected and wherein line-growth occurs preferentially along one or more of the symmetry axis' of the underlying crystalline surface.

3. The method according to claim 2 wherein the crystalline solid is selected to have a straight axis of symmetry across the surface so that line is a straight line.

4. The method according to claim 2 wherein the crystalline solid is selected to have a set of symmetry axis' such that the line formed is a curved line.

5. The method according to claim 1 wherein the gas of initiator atoms or molecules comprises a single chemical species so that when a plurality of said initiator atoms or molecules are attached to the surface having a single alignment of the induced strain relative to the surface crystalline axis', will give rise to parallel lines.

6. The method according to claim 1 including a step changing the dosing gas whereby, due to a change in the dipolar axis of the adsorbate molecule relative to the surface symmetry axis', a change in the induced strain at the surface alters the direction of line-growth for preparing variable molecular-scale patterns.

7. The method according to claim 1 wherein said dosing gas comprises atoms or molecules having an electronic structure such that the line is electrically conducting.

8. The method according to claim 1 wherein said dosing gas comprises atoms or molecules that induce charge-transfer locally, to or from the crystalline substrate, causing the substrate to become electrically conducting locally beneath the atomic or molecular line, thereby constituting a self assembled nanowire.

9. The method according to claim 1 wherein said dosing gas comprises atoms or molecules having an electronic structure such that the line is electrically insulating.

10. The method according to claim 1 including periodically changing the atoms or molecules comprising the line or lines having different chemical natures to give multi-component lines.

11. The method according to claim 1 wherein the atoms or molecules of the dosing gas are selected such that the charge-displacement can itself induce the component atoms or molecules of the line to react chemically with the surface.

12. The method according to claim 1 wherein the atoms or molecules of the dosing gas are selected such that the atoms or molecules are physisorbed in the lines, and including a step of inducing localized chemical attachment to the surface of the substrate atoms or molecules by any one or combination of heating the substrate surface, bombarding the substrate surface with light, bombarding the substrate surface with electrons, and bombarding the substrate with other charged particles.

13. The method according to claim 1 wherein the atoms or molecules of the dosing gas are selected such that the atoms or molecules are chemisorbed to the surface when the line is growing.
